(19) United States
(12) Patent Application Publication
(10) Pub. No.: US 2026/0297274 A1
(43) Pub. Date: Oct. 1, 2026

(54) POLYMER DISPERSED LIQUID CRYSTAL FILM

(71) Applicant: NITTO DENKO CORPORATION, Ibaraki-shi (JP)

(72) Inventors: Ryota MATSUMURA, Ibaraki-shi (JP); Masanori OTSUKA, Ibaraki-shi (JP); Tadashi KOBASHI, Ibaraki-shi (JP); Daisuke OGOMI, Ibaraki-shi (JP)

(21) Appl. No.: 19/578,358

(22) Filed: Mar. 25, 2026

(30) Foreign Application Priority Data
Mar. 26, 2025 (JP) 2025-051411

(51) Int. Cl. C08J 7/04; C23C 14/12; C23C 14/34

(52) U.S. Cl. CPC C08J 7/0423; C23C 14/12; C23C 14/34; C08J 2375/08

(57) ABSTRACT

Provided is a guest-host polymer dispersed liquid crystal film that can achieve both visual legibility in a transparent state and a shielding property in a scattering state. Provided is a polymer dispersed liquid crystal film, including in the following order: a first transparent conductive film; a polymer dispersed liquid crystal layer; and a second transparent conductive film, wherein the polymer dispersed liquid crystal layer contains: a polymer matrix; and liquid crystal droplets dispersed in the polymer matrix, the liquid crystal droplets each containing a liquid crystal component and a dichroic dye, and wherein when an average particle diameter of the liquid crystal droplets is represented by D (unit: nm), and an inter-droplet distance when the cumulative frequency of the inter-droplet distances accounts for 5% of the cumulative distribution of the inter-droplet distances is represented by R5 (unit: nm), a ratio R5/D is more than 0.10.

### CROSS-REFERENCE TO RELATED APPLICATIONS

This application claims priority under 35 U.S.C. Section 119 to Japanese Patent Application No. 2025-051411 filed on Mar. 26, 2025, which is herein incorporated by reference.

### BACKGROUND OF THE INVENTION

### 1. Field of the Invention

The present invention relates to a polymer dispersed liquid crystal film and a method of producing the same. The present invention also relates to a liquid crystal emulsion usable in the production of the above-mentioned polymer dispersed liquid crystal film.

### 2. Description of the Related Art

A polymer dispersed liquid crystal (hereinafter sometimes referred to as “PDLC”) film including, between a pair of transparent electrode layers, a PDLC layer containing a polymer matrix and liquid crystal droplets dispersed in the polymer matrix can change the extent to which transmitted light is scattered in accordance with the quantity of a voltage applied to the transparent electrode layers. The PDLC film can switch a state in which the light is scattered (a scattering state) and a state in which the light is transmitted (a transparent state) by, for example, switching the voltage applied to the transparent electrode layers on and off (e.g., Japanese Patent Application Laid-open No. 2002-189123). An investigation has been made on the application of the PDLC film to display bodies, such as an advertisement and a guide plate, smart windows, and the like through utilization of such function.

In addition, there is a proposal of a PDLC film (a so-called guest-host (GH)-PDLC film) including liquid crystal droplets each containing a dichroic dye (e.g., WO 2022/186062 A1). According to the GH-PDLC film, a high shielding effect may be achieved because the absorption of light is caused by the dichroic dye in a scattering state.

### SUMMARY OF THE INVENTION

The GH-PDLC film may require a high haze and a low transmittance in a scattering state (as a result, a background is highly shielded), and a low haze and a high transmittance in a transparent state (as a result, the background is clearly and sharply recognized) in accordance with its applications.

An example of a method of improving a shielding property with regard to the above-mentioned requirement includes a method of reducing a linear transmittance. In order to reduce the linear transmittance, it is necessary to increase haze or reduce a total light transmittance because the relationship of “Tp=Tt(1−H)” (Tp: linear transmittance, Tt: total light transmittance, H: haze) is established. However, when the total light transmittance in a scattering state is reduced, the shielding property may be improved, but the total light transmittance in a transparent state may be reduced. In addition, when the total light transmittance in the transparent state is increased, the total light transmittance in the scattering state is also increased, and the shielding property may be insufficient.

A primary object of the present invention is to provide a GH-PDLC film that can achieve both visual legibility in a transparent state and a shielding property in a scattering state.
[1] According to one aspect of the present invention, there is provided a polymer dispersed liquid crystal film, including in the following order: a first transparent conductive film; a polymer dispersed liquid crystal layer; and a second transparent conductive film, wherein the polymer dispersed liquid crystal layer includes: a polymer matrix; and liquid crystal droplets dispersed in the polymer matrix, the liquid crystal droplets each containing a liquid crystal component and a dichroic dye, and wherein when an average particle diameter of the liquid crystal droplets is represented by D (unit: nm), and an inter-droplet distance when the cumulative frequency of the inter-droplet distances accounts for 5% of the cumulative distribution of the inter-droplet distances is represented by R5 (unit: nm), a ratio R5/D is more than 0.10.
[2] In the polymer dispersed liquid crystal film according to the above-mentioned item [1], the liquid crystal droplets may have an average particle diameter of 500 nm or more and 2,000 nm or less.
[3] In the polymer dispersed liquid crystal film according to the above-mentioned item [1] or [2], the liquid crystal component may have a birefringence of 0.200 or more.
[4] In the polymer dispersed liquid crystal film according to any one of the above-mentioned items [1] to [3], a content ratio of the liquid crystal component in the polymer dispersed liquid crystal layer may be 30 wt % or more and 70 wt % or less.
[5] In the polymer dispersed liquid crystal film according to any one of the above-mentioned items [1] to [4], the polymer dispersed liquid crystal layer may have a thickness of 2 μm or more and 50 μm or less.

The PDLC film according to an embodiment of the present invention is a GH-PDLC film, and the dispersibility of the liquid crystal droplets in the PDLC layer is improved. Accordingly, the PDLC film can suitably achieve both visibility in a transparent state and a shielding property in a scattering state.

### BRIEF DESCRIPTION OF THE DRAWINGS

FIG. 1 is a schematic cross-sectional view for illustrating the configuration of a PDLC film according to one embodiment of the present invention.

FIG. 2A is a schematic cross-sectional view for describing the voltage non-applied state of the PDLC film illustrated in FIG. 1.

FIG. 2B is a schematic cross-sectional view for describing the voltage applied state of the PDLC film illustrated in FIG. 1.

FIG. 3A and FIG. 3B are schematic views for describing coalesced liquid crystal droplets.

FIG. 4A and FIG. 4B are schematic views for describing liquid crystal droplets each having a multimodal shape.

FIG. 5 is an observation image of a cross section obtained through use of a scanning electron microscope (SEM), the image showing liquid a crystal droplet having a multimodal shape.

FIG. 6 is a schematic view for describing an inter-droplet distance.

FIG. 7 is a schematic view for describing a method of evaluating the shielding property of a PDLC film.

FIG. 8A is an image captured via a PDLC film, and FIG. 8B is a brightness profile along a dotted line of the image.

FIG. 9 is a graph showing the cumulative distribution of inter-droplet distances (R) between liquid crystal droplets.

### DESCRIPTION OF THE EMBODIMENTS

Embodiments of the present invention are described below. However, the present invention is not limited to these embodiments. The embodiments may be appropriately combined with each other. Although the width, thickness, shape, and the like of each part may be schematically illustrated in each of the drawings for more clarity of illustration than the embodiments, the drawings are each merely an example, and the interpretation of the present invention is not limited. In this specification, the expression “from . . . to” representing a numerical range includes the upper limit and lower limit numerical values thereof.

### A. Polymer Dispersed Liquid Crystal Film

FIG. 1 is a schematic cross-sectional view for illustrating the configuration of a PDLC film according to one embodiment of the present invention. A PDLC film 100 includes a first transparent conductive film 10, a PDLC layer 20, and a second transparent conductive film 30 in the stated order. The PDLC layer 20 contains a polymer matrix 22, and liquid crystal droplets 24 that are dispersed in the polymer matrix 22, and each contain a liquid crystal component 25 and a dichroic dye 26. The first transparent conductive film 10 includes a first transparent substrate 12 and a first transparent electrode layer 14 arranged on the PDLC layer 20 side thereof. The second transparent conductive film 30 includes a second transparent substrate 32 and a second transparent electrode layer 34 arranged on the PDLC layer 20 side thereof. The first transparent conductive film 10, the PDLC layer 20, and the second transparent conductive film 30 are preferably laminated in close contact with one another without via an adhesion layer.

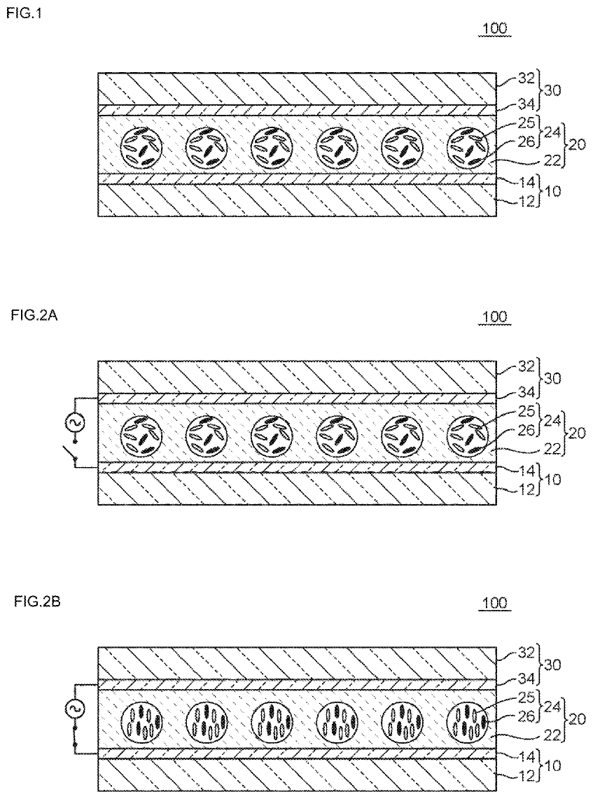

The PDLC film 100 is in a normal mode, is brought into a transparent state in a voltage applied state, and is brought into a scattering state in a voltage non-applied state. Specifically, in a voltage non-applied state, the liquid crystal component 25 and the dichroic dye 26 are not aligned as illustrated in FIG. 2A. Accordingly, scattering caused by a difference in refractive index between the polymer matrix 22 and the liquid crystal component 25, and absorption caused by the dichroic dye 26 occur. Meanwhile, in a voltage applied state, as illustrated in FIG. 2B, the liquid crystal component 25 is aligned in accordance with an electric field direction, and the dichroic dye 26 is also aligned along the liquid crystal component 25. Accordingly, the refractive index of the liquid crystal component 25 and the refractive index of the polymer matrix 22 match with each other to suppress the scattering and reduce the absorption caused by the dichroic dye 26.

Unlike the illustrated example, the PDLC film according to the embodiment of the present invention may be in a reverse mode. In the PDLC film of the reverse mode, an alignment film is arranged on the surface of the transparent conductive film on the PDLC layer side. According to the above-mentioned configuration, the liquid crystal component and the dichroic dye in the liquid crystal droplets are aligned in the voltage non-applied state to bring the PDLC film into the transparent state, and the application of a voltage can change the alignment states of the liquid crystal component and the dichroic dye to bring the PDLC film into the scattering state.

The haze of the PDLC film in the scattering state may be, for example, 80% or more, preferably from 90% to 100%. The haze of the PDLC film in the transparent state is lower than the haze of the PDLC film in the scattering state. The haze of the PDLC film in the transparent state may be, for example, 20% or less, preferably from 0% to 10%.

The total light transmittance of the PDLC film in the scattering state is, for example, 10% or less, preferably 5% or less, and may be, for example, 0.01% or more, 1% or more, or 2% or more. The total light transmittance of the PDLC film in the transparent state may be equal to or more than the total light transmittance of the PDLC film in the scattering state. The total light transmittance of the PDLC film in the transparent state may be, for example, from 10% to 70%, preferably from 20% to 70%, more preferably from 30% to 70%. The PDLC film according to the embodiment of the present invention can achieve a high shielding property even when the total light transmittance in the scattering state is relatively high. As a result, both visual legibility in the transparent state and the shielding property in the scattering state can be suitably achieved.

The driving voltage of the PDLC film according to the embodiment of the present invention may be, for example, from 20 V to 100 V, preferably from 20 V to 70 V. Herein, the driving voltage of the PDLC film means a voltage that can switch the PDLC layer from the scattering state to the transparent state or from the transparent state to the scattering state when applied to the transparent electrode layers. In this specification, the voltage applied state means a state in which the driving voltage is applied to the transparent electrode layers, and may be, for example, a state in which a voltage of 50 Vis applied.

The thickness of the PDLC film may be, for example, from 30 μm to 250 μm, preferably from 50 μm to 150 μm.

### <First Transparent Conductive Film and Second Transparent Conductive Film>

The first transparent conductive film 10 includes the first transparent substrate 12 and the first transparent electrode layer 14 arranged on one side thereof, and the second transparent conductive film 30 includes the second transparent substrate 32 and the second transparent electrode layer 34 arranged on one side thereof. An alignment film may be arranged on the surface of each of the first transparent electrode layer and the second transparent electrode layer in accordance with the driving mode of the PDLC film. The first transparent conductive film may have the same configuration as the configuration of the second transparent conductive film, or may have a configuration different therefrom. In other words, the first transparent substrate may be the same as the second transparent substrate, or may be different therefrom. In addition, the first transparent electrode layer may be the same as the second transparent electrode layer, or may be different therefrom. Hereinafter, “the first transparent conductive film and the second transparent conductive film,” “the first transparent substrate and the second transparent substrate,” and “the first transparent electrode layer and the second transparent electrode layer” are collectively described as “transparent conductive film,” “transparent substrate,” and “transparent electrode layer,” respectively.

The surface resistance value of the transparent conductive film (more specifically, the surface resistance value of the transparent electrode layer) is preferably from 1Ω/□ to 1,000Ω/□, more preferably from 5Ω/□ to 300Ω/□, still more preferably from 10Ω/□ to 200Ω/□.

The haze of the transparent conductive film is preferably 20% or less, more preferably 10% or less, still more preferably from 0.1% to 10%.

The total light transmittance of the transparent conductive film is preferably 40% or more, more preferably 60% or more, still more preferably 80% or more.

The transparent substrate may be formed by using any appropriate material. The transparent substrate is typically a polymer film containing a thermoplastic resin as a main component. Examples of the thermoplastic resin include: a polyester-based resin such as polyethylene terephthalate (PET); a cycloolefin-based resin such as polynorbornene; an acrylic resin; a polycarbonate-based resin; and a cellulose-based resin. Of those, a polyester-based resin, a cycloolefin-based resin, or an acrylic resin is preferred. Those resins are each excellent in transparency, mechanical strength, thermal stability, water barrier property, and the like. The thermoplastic resins may be used alone or in combination thereof.

The thickness of the transparent substrate may be preferably from 3 μm to 200 μm, more preferably from 5 μm to 100 μm, still more preferably from 15 μm to 70 μm.

The total light transmittance of the transparent substrate is preferably 40% or more, more preferably 60% or more, still more preferably 80% or more.

The transparent electrode layer may be formed by using, for example, a metal oxide, such as indium oxide, tin oxide, zinc oxide, an indium-tin composite oxide (ITO), a tin-antimony composite oxide, a zinc-aluminum composite oxide, or an indium-zinc composite oxide. In this case, the metal oxide may be an amorphous metal oxide or a crystallized metal oxide. In addition, the transparent electrode layer may be formed of, for example, a metal nanowire such as a silver nanowire (AgNW), a carbon nanotube (CNT), an organic conductive film, a metal layer, or a laminate thereof. A transparent electrode layer containing an ITO is preferably formed. The transparent electrode layer containing an ITO is excellent in transparency. The transparent electrode layer may be patterned into a desired shape in accordance with purposes.

The total light transmittance of the transparent electrode layer is preferably 85% or more, more preferably 87% or more, still more preferably 90% or more. When a transparent electrode layer having a total light transmittance within such ranges is used, a PDLC film having a high total light transmittance in a transparent state can be obtained. The total light transmittance is preferably as high as possible, and its upper limit is, for example, 99%.

The thickness of the transparent electrode layer may be appropriately set in accordance with desired characteristics, forming materials, and the like. The thickness of the transparent electrode layer formed from the metal oxide is, for example, 10 nm or more, preferably 15 nm or more, and is, for example, 50 nm or less, preferably 35 nm or less, more preferably 30 nm or less. The thickness of the transparent electrode layer formed from the silver nanowire is, for example, 10 nm or more, preferably 20 nm or more, and is, for example, 1,000 nm or less, preferably 500 nm or less.

The transparent conductive film may be obtained by, for example, forming the transparent electrode layer on one surface of the transparent substrate through any appropriate film formation method, such as a sputtering method, a vacuum evaporation method, a CVD method, an ion plating method, a spray method, or a coating method. After the formation of a metal oxide layer, the transparent electrode layer formed from a crystallized metal oxide can be obtained by its annealing. The annealing is performed by, for example, thermally treating the layer at from 120° C. to 300° C. for from 10 minutes to 120 minutes.

### <PDLC Layer>

The PDLC layer 20 is a GH-PDLC layer containing the polymer matrix 22, and the liquid crystal droplets 24 that are dispersed in the polymer matrix 22, and each contain the liquid crystal component 25 and the dichroic dye 26. The PDLC layer may contain any appropriate additive component in accordance with purposes. The additive component is described in the section B.

The average particle diameter of the liquid crystal droplets in the PDLC layer may be, for example, from 500 nm to 2,000 nm, preferably from 600 nm to 1,500 nm, more preferably from 800 nm to 1,200 nm. When the average particle diameter of the liquid crystal droplets falls within the above-mentioned ranges, the haze and absorption in the scattering state increase, and a high shielding property can be achieved. In this specification, the particle diameters of the liquid crystal droplets are the maximum Feret diameters of the liquid crystal droplets in an observation image of any appropriate portion of a cross section along the thickness direction of the PDLC layer. The average particle diameter of the liquid crystal droplets is the average of the particle diameters (maximum Feret diameters) of 100 or more liquid crystal droplets each having a clear outline, the droplets being randomly selected in the above-mentioned observation image. The maximum Feret diameters of the liquid crystal droplets may be obtained by, for example, analyzing the above-mentioned observation image with image analysis software such as Image J. In the above-mentioned observation image, the voids in the polymer matrix that were occupied by the liquid crystal droplets may be actually observed. In such a case, the shapes of the voids can be regarded as the shapes of the liquid crystal droplets.

The coefficient of variation (CV value) of the particle diameters of the liquid crystal droplets may be, for example, 48 or less, preferably 46 or less, more preferably 44 or less, still more preferably 42 or less. The CV value may be, for example, 10 or more. The CV value is calculated by the equation “CV value=c/D×100” from the average particle diameter (D) of the liquid crystal droplets and the standard deviation (c) thereof. When the CV value falls within the above-mentioned ranges, the haze and absorption in the scattering state increase, and a high shielding property can be achieved.

With regard to the particle diameter distribution of the liquid crystal droplets, the ratio (D90−D10)/D50 may be, for example, 1.4 or less, preferably 1.3 or less, more preferably 1.2 or less. The minimum value of the ratio (D90−D10)/D50 is 1, and as the ratio is closer to 1, the monodispersibility of the particle diameters is higher. When the ratio (D90−D10)/D50 falls within the above-mentioned ranges, the haze and absorption in the scattering state increase, and a high shielding property can be achieved. Each of D10, D50, and D90 described above is based on the maximum Feret diameters. D10 represents such a particle diameter that the ratio of particles each having a particle diameter of D10 or less is 10%, D50 represents such a particle diameter (median diameter) that the ratio of particles each having a particle diameter of D50 or less is 50%, and D90 represents such a particle diameter that the ratio of particles each having a particle diameter of D90 or less is 90%.

The intermediate value of the degrees of circularity of the liquid crystal droplets is, for example, 0.600 or more, preferably 0.650 or more, more preferably 0.700 or more, still more preferably 0.750 or more. The intermediate value of the degrees of circularity may be, for example, 0.950 or less. The median of the degrees of circularity of the liquid crystal droplets is, for example, 0.800 or more, preferably 0.810 or more, more preferably 0.820 or more, still more preferably 0.825 or more. The median of the degrees of circularity may be, for example, 0.950 or less. In addition, the average of the degrees of circularity of the liquid crystal droplets is, for example, 0.780 or more, preferably 0.800 or more, more preferably 0.810 or more, still more preferably 0.820 or more. The average of the degrees of circularity may be, for example, 0.950 or less. The above-mentioned intermediate value, median, and average of the degrees of circularity are the intermediate value ((maximum value+minimum value)/2), median, and average, respectively, of degrees of circularity obtained for the respective 100 or more liquid crystal droplets each having a clear outline, the droplets being randomly selected in the observation image of any appropriate portion of the cross section along the thickness direction of the PDLC layer. The degree of circularity is a value determined by the equation “degree of circularity=4π×(area)/(perimeter)²,” and may be obtained by, for example, analyzing the observation image with image analysis software such as Image J. The degree of circularity represents the complexity of a figure. The degree of circularity of a perfect circle represents 1 that is the maximum value, and as the figure is more complex than a circle, the degree of circularity is smaller. The intermediate value, median, or average of the degrees of circularity of the liquid crystal droplets falling within the above-mentioned ranges means that a large number of liquid crystal droplets each having a shape close to a circle are present, that is, a small number of liquid crystal droplets each having a complex shape in which two or more liquid crystal droplets coalesce are present, and may mean that the dispersibility of the liquid crystal droplets is satisfactory. When the liquid crystal droplets are satisfactorily dispersed in the PDLC layer, the haze and absorption in the scattering state increase, and a high shielding property can be achieved.

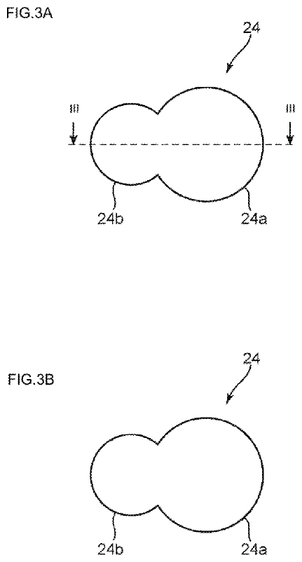

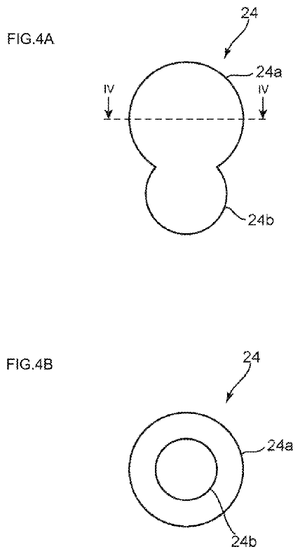

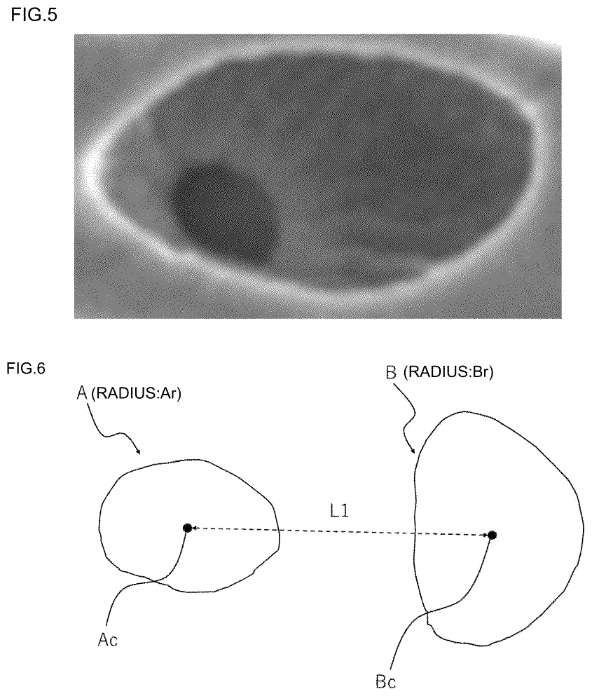

In the observation image of the cross section of the PDLC layer, the liquid crystal droplets in each of which two or more liquid crystal droplets coalesce (hereinafter sometimes referred to as “coalesced liquid crystal droplets”) may exhibit a low degree of circularity or have a multimodal shape. For example, FIG. 3A is an illustration of a coalesced liquid crystal droplet 24 formed by the coalescence of liquid crystal droplets 24a and 24b, and FIG. 3B is a cross-sectional view taken along the line III-III thereof. As illustrated in FIG. 3B, the cross-sectional shape of the coalesced liquid crystal droplet 24 is more complex than a circle is, and may exhibit a low degree of circularity. In addition, for example, FIG. 4A is an illustration of the coalesced liquid crystal droplet 24 formed by the coalescence of the liquid crystal droplets 24a and 24b, and FIG. 4B is a cross-sectional view taken along the line IV-IV thereof. As illustrated in FIG. 4B, the cross-sectional shape of the coalesced liquid crystal droplet 24 is close to a circle derived from the liquid crystal droplet 24a, and may exhibit a high degree of circularity, but the coalesced liquid crystal droplet has a shape in which a circle derived from the liquid crystal droplet 24b is further present inside the circle derived from the liquid crystal droplet 24a (i.e., a multimodal shape). FIG. 5 is an actual cross-sectional SEM image, which shows a liquid crystal droplet having a multimodal shape. As is apparent from FIG. 5, the liquid crystal droplet having a multimodal shape may be easily recognized in the observation image of the cross section.

In one embodiment, the ratio of the coalesced liquid crystal droplets in the liquid crystal droplets may be, for example, 25% or less, preferably 20% or less, more preferably 15% or less, still more preferably 10% or less, yet still more preferably 5% or less. The ratio of the coalesced liquid crystal droplets may be, for example, 0.1% or more. The ratio of the coalesced liquid crystal droplets may be obtained by: in the observation image of any appropriate portion of the cross section along the thickness direction of the PDLC layer, counting the number (A) of liquid crystal droplets each having a degree of circularity of less than 0.700 as coalesced liquid crystal droplets; selecting liquid crystal droplets having a multimodal shape from particles each having a degree of circularity of 0.700 or more; counting the number (B) of the liquid crystal droplets having a multimodal shape; and calculating the ratio from the equation “Ratio (%) of coalesced liquid crystal droplets=(A+B)/C×100”, wherein C represents the total number of liquid crystal droplets analyzed. The total number C of the liquid crystal droplets may be, for example, 100 or more. A low ratio of the coalesced liquid crystal droplets may show that the dispersibility of the liquid crystal droplets is satisfactory.

When R (unit: nm) represents an inter-droplet distance between the liquid crystal droplets, D (unit: nm) represents the average particle diameter thereof, and R5 represents the inter-droplet distance R when the cumulative frequency of the inter-droplet distances R accounts for 5% of the cumulative distribution of the inter-droplet distances, the ratio R5/D may be, for example, more than 0.10, preferably 0.12 or more, more preferably 0.14 or more, still more preferably 0.16 or more. The ratio R5/D may be, for example, 0.8 or less, or 0.7 or less. The inter-droplet distance R may be obtained by: determining the maximum Feret diameters and centroid positions of all the liquid crystal droplets (preferably 100 or more liquid crystal droplets) each having a clear outline in the observation image of any appropriate portion of the cross section along the thickness direction of the PDLC layer; calculating, for each droplet, a centroid-to-centroid distance to the centroid position of another liquid crystal droplet that has the minimum centroid-to-centroid distance therefrom; and subtracting the radii of the respective liquid crystal droplets from the centroid-to-centroid distance.

The inter-droplet distance R is described more specifically with reference to FIG. 6. FIG. 6 is an illustration of a liquid crystal droplet A and a liquid crystal droplet B located at the shortest centroid-to-centroid distance from the liquid crystal droplet A. The inter-droplet distance R of the liquid crystal droplet A is calculated as follows: a distance between the centroid position Ac of the liquid crystal droplet A and the centroid position Bc of the liquid crystal droplet B is defined as a centroid-to-centroid distance L1, and the radius Ar of the liquid crystal droplet A and the radius Br of the liquid crystal droplet B are subtracted from the L1 (R=L1−Ar−Br). When such a plurality of liquid crystal droplets that the centroid-to-centroid distances from the liquid crystal droplet A are the shortest are present, the shortest inter-droplet distance out of inter-droplet distances calculated as described above is adopted as the inter-droplet distance of the liquid crystal droplet A. The radius of each of the liquid crystal droplets is one half of the maximum Feret diameter. The maximum Feret diameters and centroid positions of the liquid crystal droplets may be obtained by identifying the shape of each of the liquid crystal droplets in the observation image, and analyzing the shape with image analysis software such as Image J. The ratio R5/D may serve as an indicator of the dispersibility of the liquid crystal droplets. Specifically, a small ratio R5/D means that a relatively large number of droplets in which the inter-droplet distance is extremely short are present, and may mean that the droplets are aggregated. Meanwhile, a large ratio R5/D means that a relatively small number of droplets in which the inter-droplet distance is extremely short are present, and may mean that the aggregation of the droplets is suppressed. The ratio R5/D is a parameter serving as an inter-droplet distance excluding the effects of particle diameters.

The polymer matrix is typically formed from a resin. A polymer matrix-forming resin may be appropriately selected in accordance with, for example, the light transmittance of the PDLC layer, the refractive index of the liquid crystal component, and the adhesive strength thereof with each of the transparent conductive films. For example, a water-dispersible resin or a water-soluble resin, such as a urethane-based resin, a polyvinyl alcohol-based resin, a polyethylene-based resin, a polypropylene-based resin, or an acrylic resin, may be used as the polymer matrix-forming resin. The polymer matrix-forming resins may be used alone or in combination thereof. A difference between the refractive index of the polymer matrix-forming resin and the ordinary refractive index or extraordinary refractive index of the liquid crystal component may be, for example, from 0.0 to 0.05.

Any appropriate liquid crystal compounds may be used alone or in combination thereof as the liquid crystal component in accordance with birefringence, the refractive index of the polymer matrix-forming resin, and the like. The dielectric anisotropy of the liquid crystal component may be positive or negative. The liquid crystal component may be, for example, a nematic liquid crystal component, a smectic liquid crystal component, or a cholesteric liquid crystal component. The nematic liquid crystal component is preferably used because high transparency in an alignment state can be achieved. The characteristics (birefringence, dielectric constant, and the like) of the liquid crystal component mean the characteristics of the liquid crystal component as a whole, which may contain two or more kinds of liquid crystal compounds.

A nematic liquid crystal compound is, for example, a biphenyl-based compound, a phenyl benzoate-based compound, a cyclohexylbenzene-based compound, an azoxybenzene-based compound, an azobenzene-based compound, an azomethine-based compound, a terphenyl-based compound, a biphenyl benzoate-based compound, a cyclohexylbiphenyl-based compound, a phenylpyridine-based compound, a cyclohexylpyrimidine-based compound, a cholesterol-based compound, or a fluorine-based compound. Those liquid crystal compounds may be used alone or in combination thereof.

The birefringence Δn of the liquid crystal component at a wavelength of 589 nm is, for example, 0.200 or more, preferably from 0.205 to 0.300, more preferably from 0.210 to 0.280. When the birefringence Δn of the liquid crystal component falls within the above-mentioned ranges, both the visual legibility in the transparent state and the shielding property in the scattering state can be suitably achieved.

Any appropriate dichroic dye that has absorption in a desired wavelength range (e.g., a desired maximum absorption wavelength) and is compatible with the liquid crystal component may be used as the dichroic dye. The dichroic dye may have a positive or negative Ac. The dichroic dye itself may exhibit liquid crystallinity. The dichroic dyes may be used alone or in combination thereof.

Specific examples of the dichroic dye include an azo-based dye, an anthraquinone-based dye, a naphthoquinone-based dye, a perylene-based dye, a quinophthalone-based dye, a tetrazine-based dye, and a benzothiadiazole-based dye. Of those, an anthraquinone-based dye or an azo-based dye is preferably incorporated as the dichroic dye from the viewpoints of, for example, an extinction coefficient, a degree of solubility in the liquid crystal component, and light resistance. For example, an azo-based dye, an anthraquinone-based dye, or a mixture thereof, which is described in “Liquid Crystal Device Handbook,” edited by Committee No. 142 of the Japan Society for the Promotion of Science, Nihon Kogyo Shimbun (1989), pp. 192-196 and pp. 724-730, may be used. In addition, various dichroic dyes are commercially available, and may be appropriately used.

The content ratio of the liquid crystal component in the PDLC layer is, for example, from 30 wt % to 70 wt %, preferably from 35 wt % to 65 wt %, more preferably from 40 wt % to 60 wt %.

The weight ratio (former: latter) of the content of the polymer matrix-forming resin to the content of the liquid crystal component in the PDLC layer is, for example, from 30:70 to 70:30, preferably from 35:65 to 65:35, more preferably from 40:60 to 60:40.

The total content ratio of the polymer matrix-forming resin and the liquid crystal component in the PDLC layer may be, for example, 80 wt % or more, preferably from 90 wt % to 99.9 wt %, preferably from 95 wt % to 99.9 wt %.

The content ratio of the dichroic dye in the PDLC layer is, for example, from 0.1 part by weight to 10 parts by weight, preferably from 1 part by weight to 10 parts by weight, more preferably from 3 parts by weight to 10 parts by weight with respect to 100 parts by weight of the liquid crystal component.

The thickness of the PDLC layer is, for example, from 2 μm to 50 μm, preferably from 4 μm to 40 μm, more preferably from 6 μm to 30 μm.

### B. Method of Producing Polymer Dispersed Liquid Crystal Film

A method of producing a PDLC film according to an embodiment of the present invention includes:
mixing a liquid crystal component, a dichroic dye, a dispersant, and an aqueous medium to provide a liquid crystal emulsion (step I);
mixing the liquid crystal emulsion and a polymer matrix-forming resin to provide an emulsion coating liquid (step II);
applying the emulsion coating liquid to a first transparent conductive film, followed by the drying of the emulsion coating liquid to provide a PDLC layer (step III); and
laminating a second transparent conductive film on the PDLC layer (step IV).

In the above-mentioned method of producing a PDLC film, the dispersant preferably contains solid particles. In the liquid crystal emulsion, liquid crystal particles each containing the liquid crystal component and the dichroic dye are dispersed in the aqueous medium. The solid particles may adsorb to an interface between the liquid crystal particles and the aqueous medium to satisfactorily emulsify the liquid crystal particles and the aqueous medium (so-called Pickering emulsification). That is, the solid particles may serve as a Pickering dispersant. A PDLC layer having excellent dispersibility of liquid crystal droplets (as a result, the PDLC film described in the section A) may be suitably obtained by preparing an emulsion coating liquid through use of the above-mentioned liquid crystal emulsion, and applying and drying the emulsion coating liquid.

### <Step I>

In the step I, the liquid crystal component, the dichroic dye, the dispersant containing solid particles, and the aqueous medium are mixed to provide the liquid crystal emulsion. As described above, the liquid crystal emulsion contains the aqueous medium, and the liquid crystal particles that are dispersed in the aqueous medium, and each contain the liquid crystal component and the dichroic dye.

The average particle diameter of the liquid crystal particles may be, for example, from 400 nm to 2,000 nm, preferably from 500 nm to 1,500 nm, more preferably from 600 nm to 1,200 nm. The particle diameters of the liquid crystal droplets in the PDLC layer may depend on the particle diameters of the liquid crystal particles in the liquid crystal emulsion. Accordingly, when the average particle diameter of the liquid crystal particles in the liquid crystal emulsion falls within the above-mentioned ranges, the average particle diameter of the liquid crystal droplets in the PDLC layer may be easily adjusted within a desired range. The average particle diameter of the liquid crystal particles means a median diameter on a number basis, and may be measured with a laser diffraction-type or dynamic light scattering-type particle size distribution measuring apparatus.

The liquid crystal component and the dichroic dye are as described in the section A. The content ratio of the liquid crystal component in the liquid crystal emulsion is, for example, from 25 wt % to 55 wt %, preferably from 30 wt % to 50 wt %. The content of the dichroic dye in the liquid crystal emulsion is, for example, from 0.1 part by weight to 10 parts by weight, preferably from 1 part by weight to 10 parts by weight, more preferably from 3 parts by weight to 10 parts by weight with respect to 100 parts by weight of the liquid crystal component.

As the solid particles, particles that can be dispersed in an aqueous phase component (specifically, the aqueous medium) and oil phase components (specifically, the liquid crystal component and the dichroic dye) that form the liquid crystal emulsion, without being dissolved in them, may be used. The solid particles each preferably have a refractive index similar to that of the liquid crystal component and/or the polymer matrix-forming resin. A difference in refractive index between the solid particles and the liquid crystal component or the polymer matrix-forming resin may be, for example, from 0.0 to 0.10.

The shapes of the solid particles are not limited, and may each be, for example, a spherical shape, a fibrous shape, a needle shape, a rod shape, a net shape, or a flaky shape.

The average particle diameter of the solid particles is preferably from 10 nm to 500 nm, more preferably from 30 nm to 300 nm, still more preferably from 50 nm to 200 nm. The average particle diameter of the solid particles is typically smaller than the average particle diameter of the liquid crystal particles, and may be, for example, 30% or less, or 15% or less of the average particle diameter of the liquid crystal particles, and may be, for example, 1% or more, or 5% or more thereof. The average particle diameter means a median diameter on a volume basis, and may be measured with a laser diffraction-type or dynamic light scattering-type particle size distribution measuring apparatus.

A material for forming the solid particles is, for example, an organic material, and examples thereof include: a resin, such as an acrylic resin, a polyurethane-based resin, a urethane acrylate-based resin, a polyether-based resin, a polyester-based resin, a styrene-based resin, a silicone-based resin, a vinyl chloride-based resin, an olefin-based resin, or a latex-based resin; and a polysaccharide, such as chitin, chitosan, cellulose, microcrystalline cellulose, or hydroxypropyl methylcellulose. The resin for forming the solid particles may have, in a side chain thereof, a functional group, such as a hydroxy group, an amino group, a carboxyl group, or a sulfo group. The solid particles may also be formed of an inorganic material, such as silica, titanium oxide, zinc oxide, iron oxide, zirconium oxide, cerium oxide, a clay mineral, or calcium carbonate. The solid particles may be, for example, water-dispersible resin particles such as acrylic resin particles, cellulose nanofibers, silica particles, talc, bentonite, or smectite. The surfaces of the silica particles may be silylated by the introduction of a trimethylsilyl group and the like. The solid particles may be used alone or in combination thereof. In addition, the solid particles may be composite particles each containing two or more kinds of materials, and may each have, for example, a core-cell structure. Of those, the acrylic resin particles have a weak interaction with the liquid crystal component and are unlikely to adversely affect the alignment of the liquid crystal component at the time of the application of a voltage, and hence the acrylic resin particles are expected to improve the visual legibility in the transparent state. Accordingly, the acrylic resin particles may be preferably used as the solid particles.

When the solid particles have an acid value, the acid value is, for example, 15 mgKOH/g or less, preferably 10 mgKOH/g or less, more preferably 8 mgKOH/g or less, still more preferably 5 mgKOH/g or less.

In one embodiment, water-dispersible resin particles are used as the solid particles. The water-dispersible resin particles are compatible with the polymer matrix-forming resin mixed in the step II. In this case, the water-dispersible resin particles form the polymer matrix with the polymer matrix-forming resin mixed in the step II, and may function as the polymer matrix-forming resin in the PDLC film to be finally obtained. A water-dispersible resin for forming the water-dispersible resin particles and the polymer matrix-forming resin may each have functional groups capable of reacting with each other. When the water-dispersible resin is chemically bonded to the polymer matrix-forming resin, phase separation may be further suppressed to form a polymer matrix having higher homogeneity. A combination of the functional groups capable of reacting with each other is, for example, an isocyanate group and an amino group, an isocyanate group and a hydroxy group, an isocyanate group and a urethane bond, a carboxyl group and an aziridine group, or a carboxyl group and an epoxy group.

The content of the solid particles in the liquid crystal emulsion is, for example, from 0.1 part by weight to 70 parts by weight, preferably from 1 part by weight to 60 parts by weight, more preferably from 5 parts by weight to 55 parts by weight, still more preferably from 10 parts by weight to 50 parts by weight with respect to 100 parts by weight of the total content of the liquid crystal component and the dichroic dye.

The dispersant may further contain another dispersant such as a surface-active-type dispersant as long as the effects of the present invention are obtained.

Water or a mixed solvent of water and a water-miscible organic solvent may be preferably used as the aqueous medium. Examples of the water-miscible organic solvent include a C1-C3 alcohol, acetone, and DMSO.

The solid content concentration of the liquid crystal emulsion is, for example, from 30 wt % to 60 wt %, preferably from 35 wt % to 55 wt %, more preferably from 40 wt % to 50 wt %.

The liquid crystal emulsion may be obtained by dispersing the components in the aqueous medium through, for example, a mechanical emulsification method, a microchannel method, a membrane emulsification method, or the like. The liquid crystal emulsion is preferably prepared by the mechanical emulsification method or the membrane emulsification method. According to the mechanical emulsification method, a liquid crystal emulsion having a small particle diameter may be efficiently obtained. The mechanical emulsification method may be performed with a publicly known dispersive mixing apparatus, such as a homomixer or a homogenizer. A homogenizer, such as a high-pressure homogenizer or an ultrasonic homogenizer, may be preferably used. In addition, according to the membrane emulsification method, an emulsion having a uniform particle size distribution may be suitably obtained. Reference may be made to the disclosures of, for example, Japanese Patent Application Laid-open No. 04-355719 and Japanese Patent Application Laid-open No. 2015-40994 (these literatures are incorporated herein by reference) for details about the membrane emulsification method.

### <Step II>

In the step II, the liquid crystal emulsion and the polymer matrix-forming resin are mixed to provide the emulsion coating liquid. The PDLC layer is formed by applying and drying the emulsion coating liquid, and hence the content ratio of each of the components excluding the aqueous medium in the emulsion coating liquid may correspond to the content ratio of each of the components in the PDLC layer.

The mixing of the liquid crystal emulsion and the polymer matrix-forming resin may be performed by, for example, mixing the liquid crystal emulsion and a resin emulsion (resin dispersion) or a resin solution containing the polymer matrix-forming resin. The polymer matrix-forming resin is as described in the section A. When the solid particles are the water-dispersible resin particles, the polymer matrix-forming resin preferably has compatibility with the water-dispersible resin for forming the solid particles. In addition, as described above, the polymer matrix-forming resin may have a functional group capable of reacting with the water-dispersible resin for forming the solid particles.

The average particle diameter of the polymer matrix-forming resin in the resin emulsion is preferably from 10 nm to 500 nm, more preferably from 30 nm to 300 nm, still more preferably from 50 nm to 200 nm. Two or more kinds of resin particles that differ in kind of a resin and/or average particle diameter may be used. The average particle diameter of the polymer matrix-forming resin means a median diameter on a volume basis, and may be measured with a laser diffraction-type or dynamic light scattering-type particle size distribution measuring apparatus.

The emulsion coating liquid may contain any appropriate additive component in accordance with purposes. Examples of the additive component include a leveling agent, a cross-linking agent, and a polymer-based protective colloid agent. Examples of the leveling agent include an acrylic leveling agent, a fluorine-based leveling agent, a silicone-based leveling agent, and an acetylene-based leveling agent. Examples of the cross-linking agent include an aziridine-based cross-linking agent and an isocyanate-based cross-linking agent. Examples of the polymer-based protective colloid agent include water-soluble polymers, such as polyvinylpyrrolidone, polyvinyl alcohol, polyethylene glycol, an ethylene oxide-propylene oxide copolymer, a polyethylene oxide adduct of glycerin, a polypropylene adduct of glycerin, a polyethylene oxide adduct of diglycerin, and a polypropylene adduct of diglycerin. The content of the additive component is preferably from 0.1 part by weight to 10 parts by weight, more preferably from 0.5 part by weight to 5 parts by weight with respect to 100 parts by weight of the solid content of the emulsion coating liquid. The additive component may be added at the time of the mixing of the liquid crystal emulsion and the polymer matrix-forming resin or the preparation of the liquid crystal emulsion.

The viscosity of the emulsion coating liquid may be preferably from 20 mPa's to 400 mPa·s, more preferably from 30 mPa·s to 300 mPa·s, still more preferably from 40 mPa's to 200 mPa·s. When the viscosity is less than 20 mPa's, the convection of a dispersion medium may become remarkable at the time of the drying of the dispersion medium to destabilize the thickness of the PDLC layer. In addition, when the viscosity is more than 400 mPa's, the beads of the emulsion coating liquid may not be stable. The viscosity of the emulsion coating liquid may be measured with, for example, a rheometer MCR302 manufactured by Anton Paar GmbH. The value of a shear viscosity under the conditions of 20° C. and a shear rate of 1,000 (1/s) is used as the viscosity herein.

The solid content concentration of the emulsion coating liquid may be, for example, from 20 wt % to 60 wt %, preferably from 30 wt % to 50 wt %.

### <Step III>

In the step III, the emulsion coating liquid is applied to the first transparent conductive film and dried to provide the PDLC layer. The emulsion coating liquid is typically applied to the surface of the first transparent conductive film on the first transparent electrode layer side.

Any appropriate method may be adopted as an application method. Examples thereof include a roll coating method, a spin coating method, a bar coating method, a dip coating method, a die coating method, a curtain coating method, a spray coating method, and a knife coating method (e.g., a comma coating method). Of those, a roll coating method is preferred. For example, reference may be made to the description of Japanese Patent Application Laid-open No. 2019-5698 for the application by the roll coating method with a slot die.

The thickness of the applied layer is preferably from 2 μm to 100 μm, more preferably from 3 μm to 90 μm, still more preferably from 5 μm to 75 μm.

The drying of the applied layer may be performed by any appropriate method. Specific examples of the drying method include natural drying, heat drying, and hot-air drying. When the emulsion coating liquid contains a cross-linking agent, the cross-linked structure of the polymer matrix may be formed at the time of the drying.

A drying temperature is preferably from 20° C. to 150° C., more preferably from 25° C. to 80° C. A drying time is preferably from 1 minute to 100 minutes, more preferably from 2 minutes to 10 minutes.

The aqueous medium is removed from the applied layer by drying the applied layer, and the polymer matrix-forming resin and the liquid crystal particles remain. As a result, a PDLC layer having a structure in which the liquid crystal droplets are dispersed in the polymer matrix is formed.

### <Step IV>

In the step IV, the second transparent conductive film is laminated on the PDLC layer. Thus, a PDLC film including the first transparent conductive film, the PDLC layer, and the second transparent conductive film in the stated order is obtained.

The lamination of the second transparent conductive film on the PDLC layer is typically performed so that the second transparent electrode layer may face the PDLC layer. From the viewpoint of obtaining sufficient adhesiveness, the lamination may be preferably performed while a lamination pressure of from 0.006 MPa/m to 7 MPa/m, more preferably a lamination pressure of from 0.06 MPa/m to 0.7 MPa/m is applied with a laminator.

### EXAMPLES

The present invention is specifically described below by way of Examples. However, the present invention is by no means limited to these Examples. Measurement methods for characteristics are as described below. In addition, the terms “part(s)” and “%” in Example and Comparative Examples are by weight unless otherwise stated.

### <Thickness>

Measurement was performed with a digital micrometer (manufactured by Anritsu Corporation, product name: “KC-351C”).

<Average Particle Diameter of Liquid Crystal Particles in Liquid Crystal Emulsion (Median Diameter on Number Basis)>

Several droplets of a liquid crystal emulsion were added to 100 ml of water to prepare a measurement sample. The measurement sample was set in the measurement holder of a laser diffraction-type particle diameter distribution-measuring apparatus (manufactured by Microtrac Retsch GmbH, apparatus name: “MT3300 EXII”), and the fact that the concentration of liquid crystal particles was measurable was recognized with the monitor of the apparatus, followed by the measurement of the average particle diameter of the liquid crystal particles with the apparatus.

### <Average Particle Diameter of Resin Particles (Median Diameter on Volume Basis)>

Several droplets of a resin dispersion were added to 100 mL of water to prepare a measurement sample. The measurement sample was set in the measurement holder of a dynamic light scattering-type particle diameter distribution-measuring apparatus (manufactured by Microtrac Retsch GmbH, apparatus name: “Nanotrac 150”), and the fact that the concentration of resin particles was measurable was recognized with the monitor of the apparatus, followed by the measurement of the average particle diameter of the resin particles with the apparatus.

### <Haze>

Measurement was performed with a haze meter (manufactured by Nippon Denshoku Industries Co., Ltd., product name: “NDH4000”) in accordance with JIS K 7136.

### <Total Light Transmittance>

Measurement was performed with a haze meter (manufactured by Nippon Denshoku Industries Co., Ltd., product name: “NDH4000”) in accordance with JIS K 7361.

### <Birefringence of Liquid Crystal Component>

A value disclosed by the manufacturer for a liquid crystal component was used.

### Example 1

### (First and Second Transparent Conductive Films)

An ITO layer was formed on one surface of a PET substrate (thickness: 50 μm) by a sputtering method to provide a transparent conductive film having the configuration [transparent substrate/transparent electrode layer].

### (Preparation of Liquid Crystal Emulsion)

32.6 Parts of a liquid crystal component containing two or more liquid crystal compounds (manufactured by JNC Corporation, product name: “JC-5240XX”, birefringence Δn=0.252 (ne=1.766, no=1.514)), 0.5 part of a dichroic dye (manufactured by Nagase Viita Co., Ltd., product name: “NKX-3739”), 1.2 parts of another dichroic dye (manufactured by Nagase Viita Co., Ltd., product name: “NKX-3708”), 41.9 parts of pure water, and 23.8 parts of a Pickering dispersant (manufactured by DIC Corporation, an aqueous dispersion of a hydroxy group-containing acrylic resin “BURNOCK WE-314”, solid content: 45%, average particle diameter: 140 nm) were mixed, and the mixture was treated with a high-pressure homogenizer to prepare a liquid crystal emulsion. The average particle diameter of liquid crystal particles in the resultant liquid crystal emulsion was 800 nm.

### (Preparation of Emulsion Coating Liquid)

56.4 Parts of the above-mentioned liquid crystal emulsion, 18.7 parts of a polyether-based polyurethane resin aqueous dispersion (manufactured by Covestro AG, product name: “NeoRez R-967”, polymer average particle diameter: 80 nm, CV value=27, solid content: 40 wt %), 0.7 part of a polymer-based protective colloid agent (manufactured by DKS Co. Ltd., product name: “PITZCOL K-90L”, solid content: 20 wt %), 0.4 part of a leveling agent (manufactured by DIC Corporation, product name: “F-444”), 1.0 part of a cross-linking agent (propylidynetrimethyl tris [3-(2-methylaziridin-1-yl)propionate]), and 22.8 parts of pure water were mixed to provide an emulsion coating liquid (solid content concentration: 35 wt %).

### (Production of PDLC Layer)

The above-mentioned emulsion coating liquid was applied to the ITO layer surface of the first transparent conductive film, and dried at 40° C. to form a PDLC layer having a thickness of 12 μm.

### (Lamination of Second Transparent Conductive Film)

While a lamination pressure of 0.4 MPa/m was applied with a laminator, the second transparent conductive film was laminated on the above-mentioned PDLC layer so that the ITO layer faced the PDLC layer. As a result, a PDLC film of a normal mode having the configuration [first transparent conductive film/PDLC layer/second transparent conductive film] was obtained.

### Comparative Example 1

### (Preparation of Liquid Crystal Emulsion)

42.3 Parts of a liquid crystal component (manufactured by JNC Corporation, product name: “JC-5240XX”, birefringence Δn=0.252 (ne=1.766, no=1.514)), 0.7 part of a dichroic dye (manufactured by Nagase Viita Co., Ltd., product name: “NKX-3739”), 1.6 parts of another dichroic dye (manufactured by Nagase Viita Co., Ltd., product name: “NKX-3708”), 55 parts of pure water, and 0.4 part of a surface-active-type dispersant (manufactured by Sanyo Chemical Industries, Ltd., “NEWPOL PE108”) were mixed, and the mixture was treated with a high-pressure homogenizer to prepare a liquid crystal emulsion. The average particle diameter of liquid crystal particles in the resultant liquid crystal emulsion was 800 nm.

### (Preparation of Emulsion Coating Liquid)

43.4 Parts of the above-mentioned liquid crystal emulsion, 31.8 parts of a polyether-based polyurethane resin aqueous dispersion (manufactured by Covestro AG, product name: “NeoRez R-967”, polymer average particle diameter: 80 nm, CV value=27, solid content: 40 wt %), 0.7 part of a polymer-based protective colloid agent (manufactured by DKS Co. Ltd., product name: “PITZCOL K-90L”, solid content: 20 wt %), 0.4 part of a leveling agent (manufactured by DIC Corporation, product name: “F-444”), 1.0 part of a cross-linking agent (propylidynetrimethyl tris [3-(2-methylaziridin-1-yl) propionate]), and 22.8 parts of pure water were mixed to provide an emulsion coating liquid (solid content concentration: 35 wt %).

### (Production of PDLC Film)

A PDLC film of a normal mode having the configuration [first transparent conductive film/PDLC layer/second transparent conductive film] was obtained in the same manner as in Example 1 except that the above-mentioned emulsion coating liquid was used.

### Comparative Example 2

### (Preparation of Liquid Crystal Emulsion)

41.7 Parts of a liquid crystal component (manufactured by JNC Corporation, product name: “JC-5240XX”, birefringence Δn=0.252 (ne=1.766, no=1.514)), 0.7 part of a dichroic dye (manufactured by Nagase Viita Co., Ltd., product name: “NKX-3739”), 1.6 parts of another dichroic dye (manufactured by Nagase Viita Co., Ltd., product name: “NKX-3708”), 55 parts of pure water, and 1.0 part of a surface-active-type dispersant (manufactured by DKS Co. Ltd., “NOIGEN ET-189”) were mixed, and the mixture was treated with a high-pressure homogenizer to prepare a liquid crystal emulsion. The average particle diameter of liquid crystal particles in the resultant liquid crystal emulsion was 800 nm.

### (Preparation of Emulsion Coating Liquid)

41.9 Parts of the above-mentioned liquid crystal emulsion, 33.3 parts of a polyether-based polyurethane resin aqueous dispersion (manufactured by Covestro AG, product name: “NeoRez R-967”, polymer average particle diameter: 80 nm, CV value=27, solid content: 40 wt %), 0.7 part of a polymer-based protective colloid agent (manufactured by DKS Co. Ltd., product name: “PITZCOL K-90L”, solid content: 20 wt %), 0.4 part of a leveling agent (manufactured by DIC Corporation, product name: “F-444”), 1.0 part of a cross-linking agent (propylidynetrimethyl tris [3-(2-methylaziridin-1-yl) propionate]), and 22.8 parts of pure water were mixed to provide an emulsion coating liquid (solid content concentration: 35 wt %).

### (Production of PDLC Film)

A PDLC film of a normal mode having the configuration [first transparent conductive film/PDLC layer/second transparent conductive film] was obtained in the same manner as in Example 1 except that the above-mentioned emulsion coating liquid was used.

### <Cross-Sectional SEM Observation>

A cross section along the thickness direction of each of the PDLC films was prepared by microtome cutting in a cooling environment, washed with hexane, and then subjected to conductive treatment to provide a sample for cross-sectional observation. The cross section of the above-mentioned sample was observed with a field emission scanning electron microscope (product name: “SU 8220”, manufactured by Hitachi High-Tech Corporation). In the observation, an acceleration voltage was set to 3 kV. The observation image was a secondary electron image, and a magnification was set to 5,000 times.

### <Particle Diameters of Liquid Crystal Droplets>

The average particle diameter of liquid crystal droplets was determined with image analysis software “Image J.” Specifically, the following operations were performed.

The cross-sectional SEM image of any appropriate portion of each of the PDLC films was enlarged to a maximum, and 100 or more voids each having a clear outline were randomly selected. At this time, a void overlapping the edge of the image was excluded from analysis (the same applies to the following image analysis). The shapes of those voids correspond to the shapes of the liquid crystal droplets. The shape of each of the voids was determined by accurately tracing the outline of the void. “Feret's diameter” was selected in the analysis tool of “Image J,” and the analysis was performed to determine the maximum Feret diameter of each of the voids each having the determined shape. An average particle diameter D and a standard deviation σ were calculated from the maximum Feret diameters of all the analyzed voids. The standard deviation σ was divided by the average particle diameter D to determine a CV value (=c/D×100). In addition, particle diameters D10, D50, and D90 on a number basis were determined from the maximum Feret diameter distribution of all the analyzed voids.

### <Degrees of Circularity and Degree of Coalescence of Liquid Crystal Droplets>

The cross-sectional SEM image of any appropriate portion of each of the PDLC films was enlarged to a maximum, and 100 or more voids each having a clear outline were randomly selected. The shape of each of the voids was determined by accurately tracing the outline of the void. The degree of circularity of each of the voids was determined by analyzing the determined shapes with the analysis tool of “Image J.” In addition, the number of the voids each having a degree of circularity of less than 0.700 was counted as coalesced liquid crystal droplets A. Further, the number of the voids each having a hole (having a multimodal shape) out of the voids each having a degree of circularity of 0.700 or more was counted as coalesced liquid crystal droplets B. The ratio of the coalesced liquid crystal droplets in all the analyzed voids was calculated as a degree of coalescence (degree of coalescence (%)=(number of coalesced liquid crystal droplets A+number of coalesced liquid crystal droplets B)/total number of analyzed voids×100).

### <Inter-Droplet Distances of Liquid Crystal Droplets>

The cross-sectional SEM image of any appropriate portion of each of the PDLC films was enlarged to a maximum, and all voids each having a clear outline were selected. The number of the selected voids was 100 or more. The shape of each of the voids was determined by accurately tracing the outline of the void. The maximum Feret diameter and centroid position of each of the voids were determined by analyzing the determined shapes with the analysis tool of “Image J.” In the determination of the centroid position, “Center of mass” was selected as a measurement condition setting and the analysis was performed. The centroid position closest to the centroid position of each of all the voids was determined, and a centroid-to-centroid distance between the two centroid positions was calculated. The inter-droplet distance R was determined by subtracting the radii of the respective voids from the above-mentioned centroid-to-centroid distance. In addition, the distance R5 was determined from the distribution of the inter-droplet distances Rs of all the voids.

### <Shielding Property>

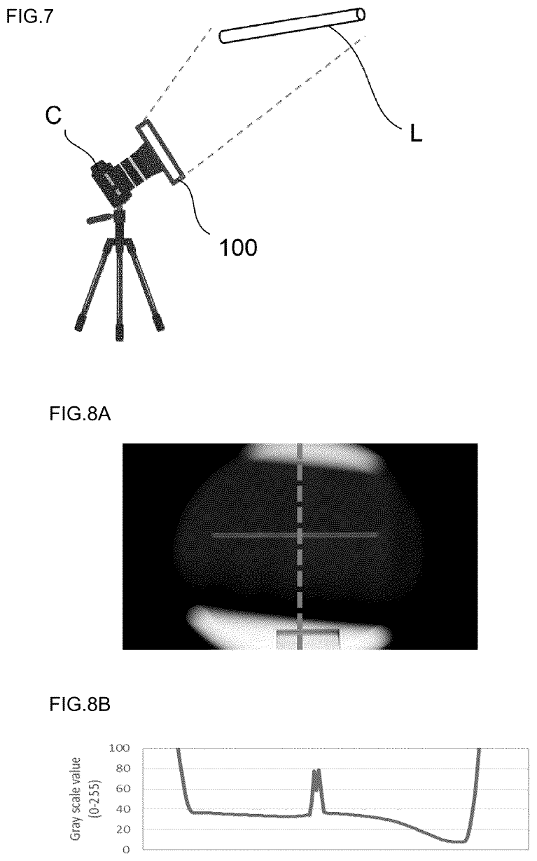

As illustrated in FIG. 7, a lit fluorescent lamp L was photographed with a camera C including the PDLC film 100 in a voltage non-applied state attached to the surface of a lens. At this time, the angle of the camera was adjusted so that the width direction of the resultant image was parallel to the longitudinal direction of the fluorescent lamp. A distance between the PDLC film and the fluorescent lamp was about 170 cm. In addition, the photographing was performed under the conditions of an ISO sensitivity of ISO640, an “f” number of F10, and a shutter speed of 1/10.

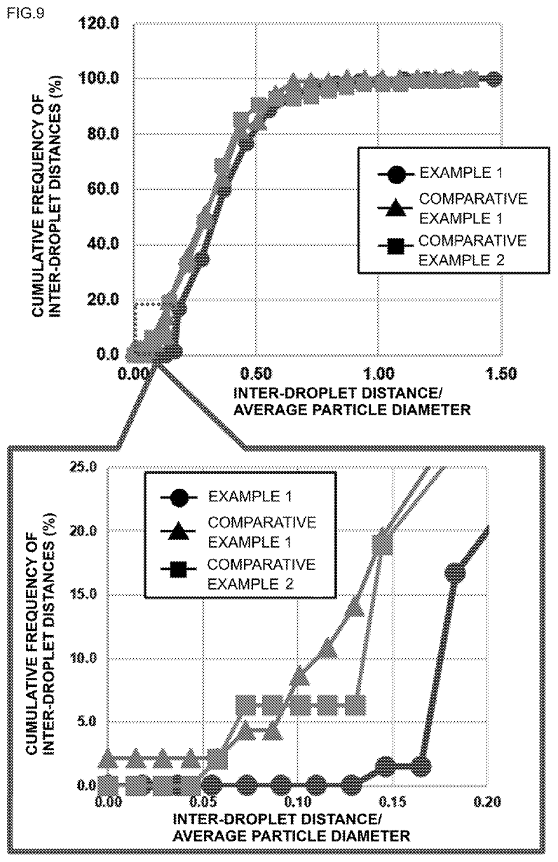

In the resultant image, a brightness profile along a straight line intersecting the fluorescent lamp and extending in a direction perpendicular to its longitudinal direction was obtained. The peak height (in other words, the difference in brightness) of a portion corresponding to the fluorescent lamp relative to the base line of the brightness profile was used as the indicator of a shielding property. FIG. 8A shows an example of the image obtained by photographing the fluorescent lamp. FIG. 8B is the brightness profile along the straight line (in FIG. 8A, a dotted line extending in the vertical direction) intersecting the fluorescent lamp and extending in the direction perpendicular to its longitudinal direction in the image, and the shielding property of the PDLC film used in the photographing is 40. As the peak height of the portion corresponding to the fluorescent lamp is smaller, the shielding property is higher.

The above-mentioned evaluation results are shown in Table 1 together with total light transmittances and hazes in a scattering state (voltage non-applied state) and a transparent state (in a state of the application of a voltage of 50 V). In addition, the cumulative distribution of the inter-droplet distances R is shown in FIG. 9.

TABLE 1

| | | Example | Comparative | Comparative |
|---|---|---|---|---|
| | | 1 | Example 1 | Example 2 |
| Particle diameter | Average particle | 1,091 | 1,383 | 1,381 |
| | diameter (D) (nm) | | | |
| | CV value | 41 | 50 | 56 |
| | (D90 − D10)/D50 | 1.2 | 1.5 | 1.5 |
| Degree of circularity | Median | 0.829 | 0.795 | 0.715 |
| | Average | 0.826 | 0.765 | 0.689 |
| | Maximum value | 0.924 | 0.946 | 0.913 |
| | Minimum value | 0.636 | 0.248 | 0.211 |
| | Intermediate value | 0.780 | 0.597 | 0.562 |
| Degree of coalescence (%) | | 2 | 30 | 52 |
| R5/D | | >0.16 | <0.10 | <0.10 |
| Maximum inter-droplet distance (nm) | | 1,264 | 1,296 | 1,944 |
| Minimum inter-droplet distance (nm) | | 165 | 20 | 92 |
| Haze (%) | Scattering state | 98.8 | 98.6 | 98.1 |
| | Transparent state | 8.3 | 10.6 | 12.8 |
| Total light | Scattering state | 3.0 | 4.3 | 2.5 |
| transmittance (%) | Transparent state | 45.7 | 45.6 | 36.9 |

| | | | |
|---|---|---|---|
| Shielding property | 9 | 13 | 15 |

The PDLC film of Example exhibited the same or higher total light transmittance in the transparent state, and exhibited a more excellent shielding property in the scattering state as compared to the PDLC films of Comparative Examples. In addition, in the cross-sectional SEM observation of the PDLC film of Example, solid particles (specifically, water-dispersible resin particles) were not identified. Accordingly, it is conceivable that the solid particles are integrated with a polymer matrix-forming resin to form a polymer matrix.

### INDUSTRIAL APPLICABILITY

The PDLC film of the present invention is suitably applicable to, for example, display bodies, such as an advertisement and a guide plate, and a smart window.

Many other modifications will be apparent to and be readily practiced by those skilled in the art without departing from the scope and spirit of the invention. It should therefore be understood that the scope of the appended claims is not intended to be limited by the details of the description but should rather be broadly construed.

What is claimed is:

1. A polymer dispersed liquid crystal film, comprising in the following order:
a first transparent conductive film;
a polymer dispersed liquid crystal layer; and
a second transparent conductive film,
wherein the polymer dispersed liquid crystal layer includes:
a polymer matrix; and
liquid crystal droplets dispersed in the polymer matrix, the liquid crystal droplets each containing a liquid crystal component and a dichroic dye, and
wherein when an average particle diameter of the liquid crystal droplets is represented by D (unit: nm), and an inter-droplet distance when the cumulative frequency of the inter-droplet distances accounts for 5% of the cumulative distribution of the inter-droplet distances is represented by R5 (unit: nm), a ratio R5/D is more than 0.10.

2. The polymer dispersed liquid crystal film according to claim 1, wherein the liquid crystal droplets have an average particle diameter of 500 nm or more and 2,000 nm or less.

3. The polymer dispersed liquid crystal film according to claim 1, wherein the liquid crystal component has a birefringence of 0.200 or more.

4. The polymer dispersed liquid crystal film according to claim 1, wherein a content ratio of the liquid crystal component in the polymer dispersed liquid crystal layer is 30 wt % or more and 70 wt % or less.

5. The polymer dispersed liquid crystal film according to claim 1, wherein the polymer dispersed liquid crystal layer has a thickness of 2 μm or more and 50 μm or less.
